(19) United States
(12) Patent Application Publication
(10) Pub. No.: US 2014/0055159 A1
(43) Pub. Date: Feb. 27, 2014

(54) Interposer with Edge Probe Points

(71) Applicants: Robert C. Shelsky, Nashua, NH (US); Kenneth W. Graham, Plainville, MA (US); Dennis D. Everson, Banks, OR (US)

(72) Inventors: Robert C. Shelsky, Nashua, NH (US); Kenneth W. Graham, Plainville, MA (US); Dennis D. Everson, Banks, OR (US)

(73) Assignee: Nexus Technology, Nashua, NH (US)

(21) Appl. No.: 13/769,382

(22) Filed: Feb. 17, 2013

Related U.S. Application Data
(60) Provisional application No. 61/601,137, filed on Feb. 21, 2012.

(51) Int. Cl. G01R 1/04; H05K 3/40; G01R 3/00

(52) U.S. Cl. CPC G01R 1/0408; G01R 3/00; H05K 3/4038
USPC 324/756.07; 361/783; 29/843

(57) ABSTRACT

An interposer is shown with contact points on a lateral edge. When assembled between a board under test and an integrated circuit, traces of the interposer carry signals between the board under test and the integrated circuit and also between signal lines of the integrated circuit and the lateral edge contact points. The signals can then be accessed by test equipment at the lateral edge contact points. The interposer may include additional components connected to the traces.

### PRIORITY

This application claims the benefit of U.S. patent application Ser. 61/601,137 filed on Feb. 21, 2012 titled Interposer with lateral probe points.

### BACKGROUND

To understand operation of a specific component in a circuit it is often necessary to characterize individual signals of the device while it is connected to other functional components. Where the signals are carried by connections which are not readily accessible, such as ball grid arrays, it can be very difficult to find an exposed trace or lead to probe with test equipment. Interposers are used to provide access to a signal from outside the footprint of the component. Often interposers are large socket type assemblies with long complex traces that introduce parasitics into the signal.

### SUMMARY

An ideal interposer does not change the character of the signal in bringing it outside the component footprint. A low profile interposer with short traces and signal conditioning would provide an improved signal characterization solution.

An interposer associated with an integrated circuit package and a board under test including a substrate with a top surface, a bottom surface and edge surfaces connecting the top and bottom surfaces. An array of contacts on the substrate top surface are soldered to an array of contacts of the integrated circuit package and a corresponding array of contacts on the substrate bottom surface are soldered to contacts of the board under test. A through connection electrically connects each corresponding top contact to a corresponding bottom contact. A plurality of contacts on the edge or lateral surface makes an electrical connection between the plurality of edge surface contacts and at least one through connection.

In an alternative embodiment, a circuit test assembly is disclosed that includes an integrated circuit package with a contact array, a board under test with a contact array corresponding to the contact array of the integrated circuit and an interposer with a contact array on a top surface soldered to the contact array of the integrated circuit. A contact array on the interposer bottom surface is soldered to a corresponding contact array of the board under test. Further including an electrical connection between each of a set of top contacts and a corresponding bottom contact and at least one electrical connection between the probe point and a contact of the top array.

Alternatively, an edge of a circuit board connecting a top surface and a bottom surface is described having an exposed edge conductor spanning the edge from the top surface to the bottom surface electrically connected to a via that opens at the top surface and the bottom surface where the via that opens at the top surface and the bottom surface carries a signal between an integrated circuit to a board under test.

### LIST OF FIGURES

FIG. 1 is an exploded view of an interposer system including an integrated circuit, an interposer and a board under test.

FIG. 2 shows an interposer including pads, lateral edge contacts, traces connecting a pad to an edge contact and additional components.

FIG. 3 is a perspective view of a portion of an interposer with portions of vias as edge contacts.

FIG. 4 is a flow chart of an interposer configuration method.

### DESCRIPTION

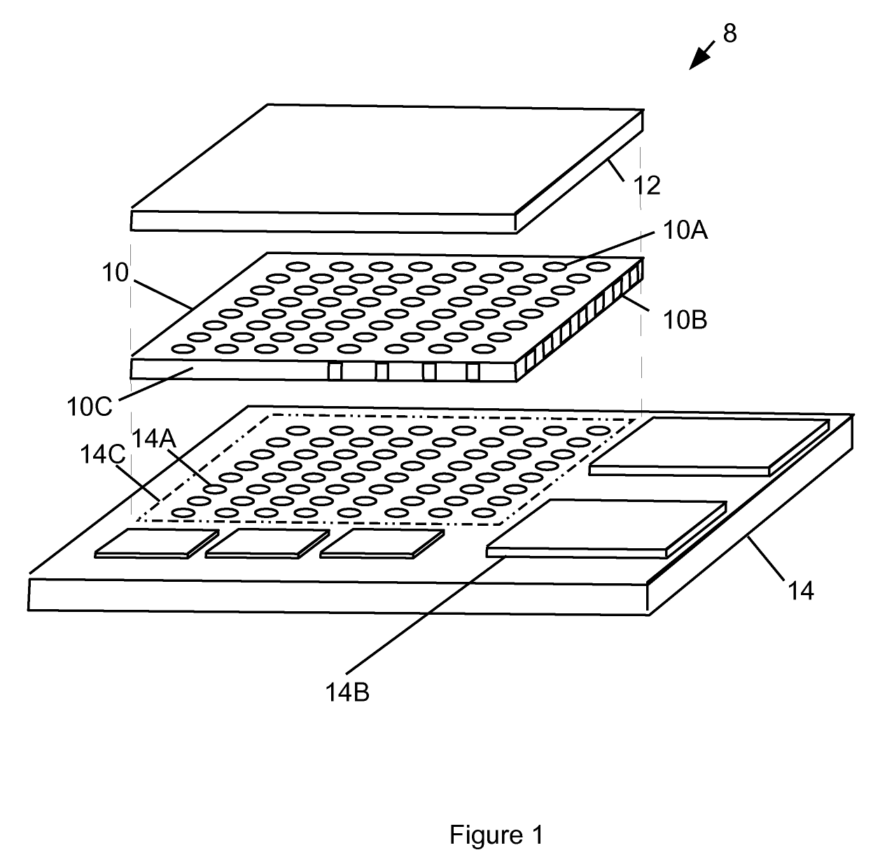

FIG. 1 shows an interposer system 8 including an interposer 10, an integrated circuit or integrated circuit package 12 and a board under test 14. Interposer 10 is shown with surface contacts or pads 10A and probe points or edge contacts 10B on a lateral edge 100 of interposer 10.

Interposer 10 may include first and second sides each with a corresponding array of pads or contacts on an insulating substrate. An array of pads for only one side is shown. Each interposer pad may be electrically connected to a corresponding pad of the opposite side. Integrated circuit 12 and board under test 14 may each include a corresponding array of pads. Array of pads 14A of board under test 14 are shown and pads of integrated circuit 12 are not shown. The pads 14A are shown in an array. The array can include any number of contacts. The pad size and array configuration may vary and the pads can be vias, electroplated contacts with traces or other configuration.

When interposer 10 is assembled stacked between integrated circuit 12 and board under test 14, signals can pass between board under test 14 and integrated circuit 12 in a through connection between corresponding contacts. Contacts of the arrays may include solder and system assembly may include reflow of the solder. The arrays may be a ball grid array configuration with solder on each contact. Ball grid array configurations and connection methods are well known to those skilled in the art.

Board under test 14 may include additional board under test components 14B assembled to the board such as discrete passive components, memory and processors. Interposer 10 may have a footprint similar to integrated circuit 12 so interposer 10 may be assembled to board under test 14 without interfering with components 14B. Interposer 10 may be within the footprint 14C of integrated circuit 12 shown as projected on board under test 14 in FIG. 1. In an alternate configuration, interposer 10 profile may extend beyond the footprint 14C of integrated circuit 12 when attached the the contact array of the board under test.

An array of contacts includes a plurality of contacts in a repeating pattern on one side of an insulating board. The repeating pattern may be repeating rows with contacts at regular intervals. The repeating pattern may include staggered rows of contacts. A separate set of contacts with the same repeating pattern occurs on the opposite side of the insulating board. If the insulating board has a point of origin at one corner and each contact on the bottom of the board has an orthogonal xy coordinate, the top of the board will have corresponding contacts with the same xy coordinate.

Some or all of contacts have an electrical connection between corresponding top and bottom contacts such as top and bottom pads with a trace between them or a via. A via for the purposes of this disclosure is a conductor that passes vertically through a circuit board opening to top and bottom surfaces of the board. The via may be a plated through hole, a trace or a filled hole that electrically connects a contact to a corresponding contact. Corresponding top and bottom contacts may include a plated pad, a solder ball or the exposed top of a via, Alternatively, corresponding top and bottom contacts may comprise the ends of a spring contact or other conductor passing through the board.

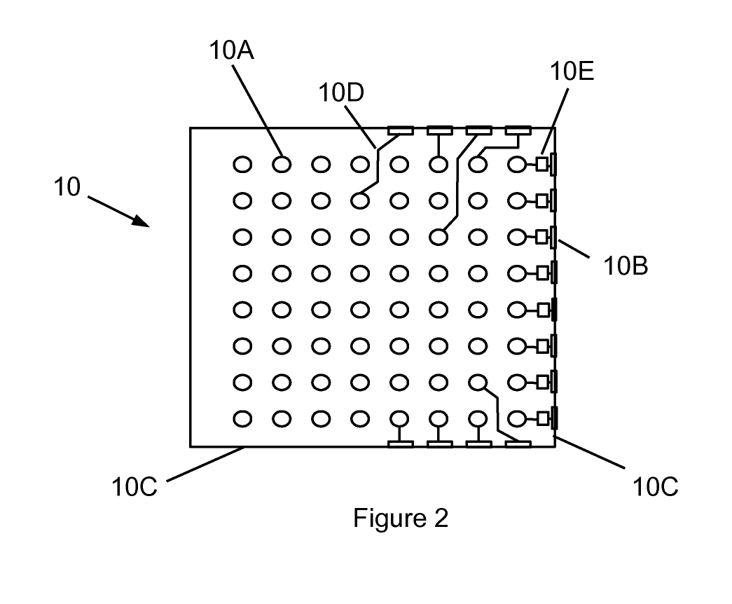

FIG. 2 shows interposer 10 with pads 10A, edge contacts 10B on lateral edge 100 and traces or electrical connections 10D for carrying signals between a pad 10A and an edge contact 10B. Interposer 10 is also shown with components 10E which may include capacitors, resistors, diodes or other electrical components. Components 10E condition signals carried on traces 10D. Alternatively, interposer 10 may be free of electrical components other than conductors.

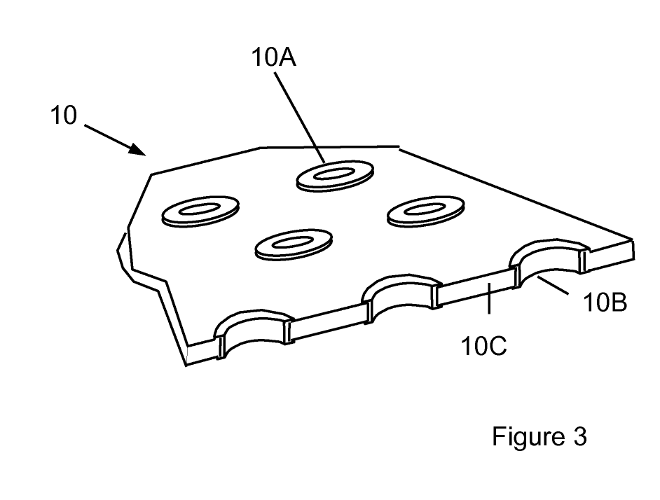

Creating an edge contact may include cutting through a circuit board so that one or more vias are sectioned and exposed by the cut. FIG. 3 is a perspective view of a portion of an interposer 10 similar to the previous figures. Here edge contact 10B is a portion of a via where the board edge 100 has been created by cutting through a substrate with vias. The cut through the board has passed through a row of vias so that a portion of each via is exposed on the edge to create a set of edge contacts 10B.

Alternatively, the edge contacts can be electroplated onto interposer edge 100 to create edge contact 10B. Other methods may be used and these techniques are well known to those skilled in the art.

Lateral edge 100 of interposer 10 includes the entire perimeter of interposer 10 connecting the top and bottom surfaces. The edge may be perpendicular to the top and bottom surfaces or edge 100 may be inclined to make it more accessible when assembled to the board under test. Edge contacts 10B may provide probe access to operating signals between board under test 14 and integrated circuit 12. Test equipment may access a signal at edge contact 10B.

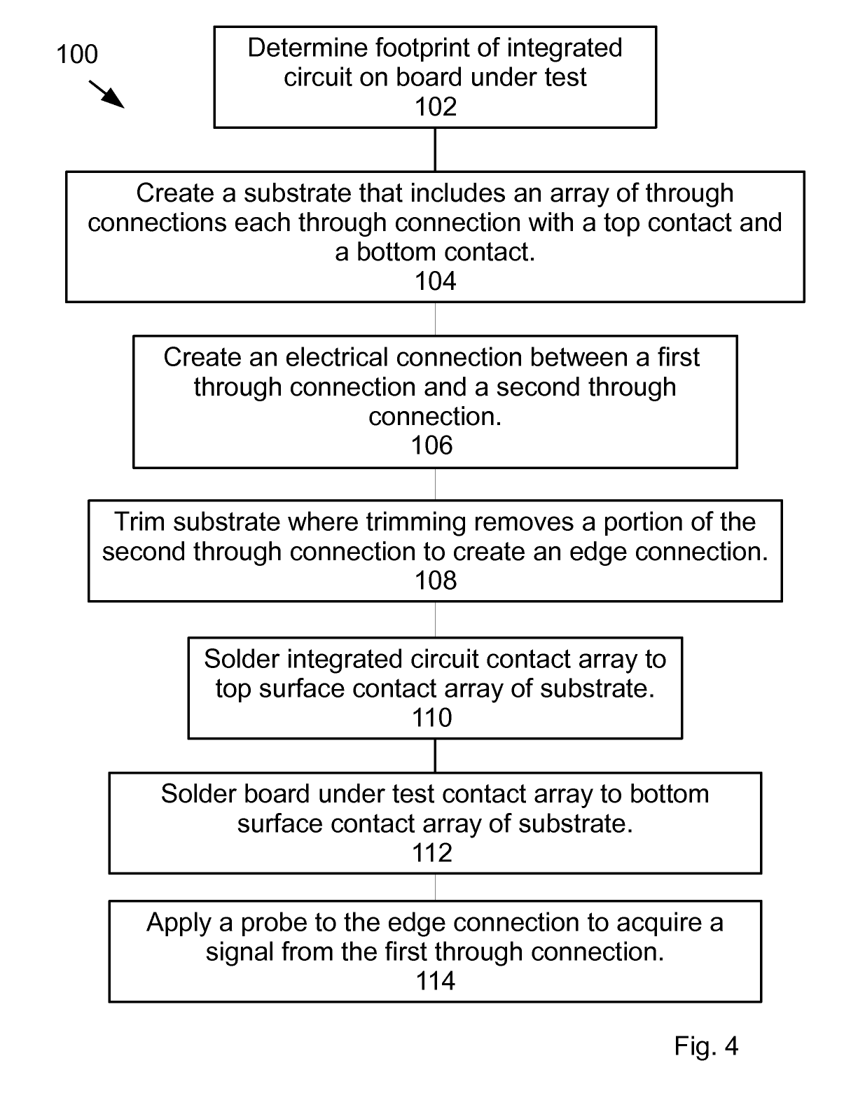

FIG. 4 is a flow chart of an interposer configuration method 100. In step 102 determine an integrated circuit footprint on a board under test where the board under test and the integrated circuit include corresponding contact arrays. In step 104 create a substrate that includes an array of through connections each with a top surface contact and a bottom surface contact. In step 106 include on the substrate at least one electrical connection between a first through connection and a second through connection. Trim the substrate in step 108, where trimming the substrate includes removing a portion of the second connection to create an edge connection. In step 110 solder the integrated circuit contact array to the top surface contact array of the substrate and solder the board under test contact array to the bottom surface contact array of the substrate in step 112. With the interposer assembled to the integrated circuit and the board under test to form a functioning electrical circuit, apply a probe to an edge connection to acquire a signal from the first through connection at step 114. Creating an electrical connection between first and second through connections may include connecting electrical components in the circuit.

This method of creating an interposer is reliable and low cost. The substrate of interposer 10 may be a multilayer substrate with traces on inner layers to create circuits. Electrical components such as resistors, capacitors and inductors may be configured on inner layers as well. Electrical components may be included on the substrate surface. The substrate of interposer 10 may be FR4, ceramic or other insulating material. Contacts and electrical connections may be copper, lead, silver aluminum or other conductor. The steps of method 100 may be performed in any order. The order shown is an example for explanation.

The physical configurations shown are examples for the purpose of explanation as well. Interposer 10 may have any number of pads and edge contacts and may be in a configuration different than that shown here. Interposer 10 may be configured to be used with interconnection systems other than ball grid arrays.

The described system and assemblies are examples and are not to be used as limitations. The number of contacts and layout or arrays can vary widely. Any suitable configuration or combination of components intended to perform a similar function will fall within the scope of this disclosure.

1. An interposer associated with an integrated circuit package and a board under test including:
a substrate with:
a top surface;
a bottom surface;
edge surfaces connecting the top and bottom surfaces;
an array of contacts on the substrate top surface soldered to an array of contacts of the integrated circuit package;
a corresponding array of contacts on the substrate bottom surface soldered to contacts of the board under test;
through connections between corresponding top and bottom contacts;
a plurality of contacts on the edge surfaces; and
an electrical connection between at least one of the plurality of edge surface contacts and at least one through connection.

2. The interposer of claim 1 where the substrate is soldered to the integrated circuit package and the board under test.

3. The interposer of claim 2 where signals pass between the integrated circuit and the board under test through the through connections.

4. The interposer of claim 3 where the at least one of the plurality of edge surface contacts is connected to a signal line.

5. The interposer of claim 1 where the at least one edge contact is insulated from the board under test.

6. The interposer of claim 1 where the electrical connection between at least one of the plurality of edge surface contacts and at least one through connection includes components to condition the electrical signal.

7. The interposer of claim 1 where the edge surface contact is a portion of a via.

8. The interposer of claim 1 where the edge surface contact is a plated conductor.

9. A circuit test assembly including:
an integrated circuit package with a contact array;
a board under test with a contact array, each contact corresponding to a contact of the integrated circuit;
an interposer with:
a contact array on a top surface soldered to the contact array of the integrated circuit;
a contact array on the bottom surface soldered to the contact array of the board under test;
electrical connections between each of a subset of the top contacts to its corresponding bottom contact;
an edge surface connecting top and bottom surfaces with at least one probe point; and
an electrical connection between a probe point and a contact of the array on the top surface.

10. The circuit test assembly of claim 9 where the electrical connections between a probe point and an electrical connection between top and bottom solder pads includes at least one component from the group of resistor, capacitor and inductor.

11. The circuit test assembly of claim 11 where the at least one component is on an inner layer of the interposer.

12. The circuit test assembly of claim 9 where the at least one probe point is connected to at least one electrical connection between corresponding top and bottom solder pads where the electrical connection carries a digital signal.

13. The circuit test assembly of claim 9 where the at least one probe point and the board edge are created by cutting through through a circuit board and through a via on the circuit board.

14. The circuit test assembly of claim 13 where the bottom surface of the interposer is electrically insulated at the probe point.

15. The circuit test assembly of claim 9 where each interposer contact of the top surface is electrically connected to its corresponding contact on the bottom surface.

16. An edge of a circuit board connecting a top surface and a bottom surface having;
an exposed edge conductor spanning the edge from the top surface to the bottom surface electrically connected to a via that opens at the top surface and the bottom surface where the via that opens at the top surface and the bottom surface carries a signal between an integrated circuit to a board under test.

17. The circuit board edge of claim 16 further including a plurality of exposed conductors on the edge of the circuit board.

18. The circuit board edge of claim 17 where each of the plurality of exposed conductors is connected to at least one via of an array of vias that open to the top and bottom surfaces.

19. The circuit board edge of claim 16 where the exposed edge conductor electrically connected to the via accesses a signal between the integrated circuit and the board under test.

20. A method of configuring an interposer comprising:
determine an integrated circuit footprint on a board under test where the board under test and the integrated circuit include corresponding contact arrays;
create a substrate that includes an array of through connections each with a top surface contact and a bottom surface contact and at least one electrical connection between a first through connection and a second through connection;
trim the substrate, where trimming the substrate includes removing a portion of the second connection to create an edge connection;
solder the integrated circuit contact array to the top surface contact array of the substrate;
solder the board under test contact array to the bottom surface contact array of the substrate; and
apply a probe to an edge connection to acquire a signal from the first through connection.

21. The method of configuring an interposer of claim 20 where the substrate includes electrical components that condition the signal between the first though connection and the edge connection.
